(19) United States
(12) Patent Application Publication
(10) Pub. No.: US 2025/0254897 A1
(43) Pub. Date: Aug. 7, 2025

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: SHIH-EN LAI, TAICHUNG CITY (TW); KAU-CHU LIN, TAICHUNG CITY (TW); CHAN-YU HUNG, TAINAN CITY (TW); FEI-YUN CHEN, HSINCHU (TW)

(21) Appl. No.: 18/433,487

(22) Filed: Feb. 6, 2024

(51) Int. Cl. H01L 23/522; H01L 27/06

(52) U.S. Cl. CPC H10D 1/692; H01L 23/5223; H01L 23/5226; H10D 84/811

(57) ABSTRACT

A semiconductor device and a method of manufacturing the same are provided. The semiconductor device includes a substrate, a transistor, and a capacitor structure. The transistor includes a gate electrode material. The capacitor structure includes a first electrode and a second electrode including the gate electrode material. The capacitor structure also includes a plurality of first conductive features disposed over the first electrode and a plurality of conductive vias disposed over a corresponding one of the plurality of first conductive features. The capacitor structure further includes a third electrode over the plurality of conductive vias and electrically connected to the first electrode through the plurality of first conductive features and the plurality of conductive vias.

### BACKGROUND

The technological evolution of integrated circuit (IC) materials and design has led to smaller and more complex circuits with each generation. In the course of such IC evolution, functional density (i.e., the number of interconnected devices per chip area) has generally increased while geometric size (i.e., the smallest component (or line) that may be created using a fabrication process) has decreased. This scaling down provides the benefits of increased production efficiency and lower associated costs.

Scaling down has further increased the complexity of IC manufacture, such that for the advances to be fully realized, corresponding developments in IC manufacture are needed.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 illustrates a perspective view of a semiconductor device, in accordance with some embodiments of the present disclosure.

FIG. 2 and FIG. 3 illustrate the layouts of the parallel capacitors as shown in FIG. 1, in accordance with some embodiments of the present disclosure.

FIG. 4 illustrates a cross-sectional view along line A-A′ of the semiconductor device as shown in FIG. 2 and FIG. 3, in accordance with some embodiments of the present disclosure.

FIG. 5 illustrates a cross-sectional view along line B-B′ of the semiconductor device as shown in FIG. 2 and FIG. 3, in accordance with some embodiments of the present disclosure.

FIG. 6 illustrates a cross-sectional view of a semiconductor device, in accordance with some embodiments of the present disclosure.

FIG. 7 illustrates a perspective view of a semiconductor device, in accordance with some embodiments of the present disclosure.

FIG. 8 illustrates the layout of a parallel capacitor as shown in FIG. 7, in accordance with some embodiments of the present disclosure.

FIG. 9 illustrates a cross-sectional view along line C-C′ of the semiconductor device as shown in FIG. 8, in accordance with some embodiments of the present disclosure.

FIG. 10 illustrates a perspective view of a semiconductor device, in accordance with some embodiments of the present disclosure.

FIG. 11 illustrates the layouts of parallel capacitors as shown in FIG. 10, in accordance with some embodiments of the present disclosure.

FIG. 12 illustrates a cross-sectional view along line D-D′ of the semiconductor device as shown in FIG. 11, in accordance with some embodiments of the present disclosure.

FIG. 13 illustrates a cross-sectional view along line E-E′ of the semiconductor device as shown in FIG. 11, in accordance with some embodiments of the present disclosure.

FIG. 14, FIG. 15, and FIG. 16 illustrate various stages of manufacturing a semiconductor device, in accordance with some embodiments of the present disclosure.

FIG. 17 is a flowchart of a method for manufacturing a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain error necessarily resulting from the standard deviation found in the respective testing measurements. Also, as used herein, the terms “substantially,” “approximately” and “about” generally mean within a value or range that can be contemplated by persons having ordinary skill in the art. Alternatively, the terms “substantially,” “approximately” and “about” mean within an acceptable standard error of the mean when considered by one of ordinary skill in the art. Persons having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the like thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure is related to semiconductor devices and fabrication methods. More particularly, the present disclosure is related to a semiconductor device including a capacitor structure. The capacitor structure includes bottom electrodes that are formed by processes for forming the gate electrode of a transistor, which thereby increases capacitance without additional steps and masks. Said capacitor structure may be applicable to, for example, a metal-insulator-metal (MIM) capacitor, a metal-oxide-metal (MOM) capacitor, a finger metal-oxide-metal (FMOM) capacitor, or the like. Further, the processes for manufacturing the capacitor structure of the present disclosure can be integrated with those for producing planar transistors, fin field-effect transistors (FinFETs), gate-all-around (GAA) transistors, or the like.

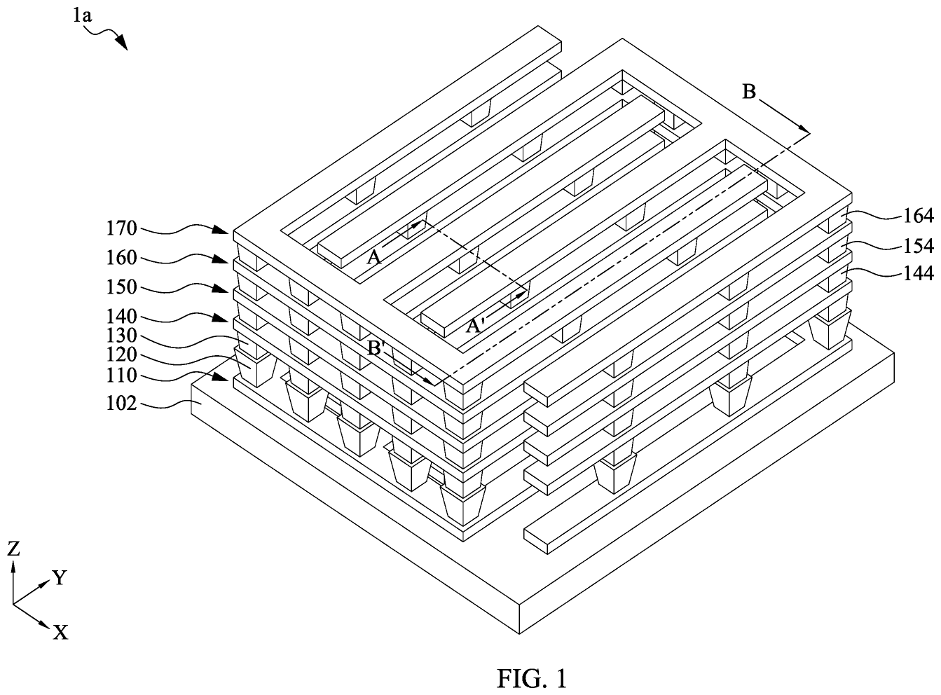

FIG. 1 illustrates a perspective view of a semiconductor device 1a, in accordance with some embodiments of the present disclosure. The semiconductor device 1a may include a capacitor structure. It should be noted that some elements and/or features are omitted from FIG. 1 for brevity.

In some embodiments, the semiconductor device 1a may include a substrate 102. The substrate 102 has multiple regions (e.g., a transistor region, a capacitor region, or the like) on which a transistor, a capacitor structure, or other suitable devices are formed.

In some embodiments, the semiconductor device 1a includes a parallel capacitor 110. The parallel capacitor 110 is disposed on or over the substrate 102. The parallel capacitor 110 may be fabricated by the processes for forming the gate electrode of a transistor, which will be described later.

In some embodiments, the semiconductor device 1a includes conductive features 120. Each of the conductive features 120 is disposed over and electrically connected to the parallel capacitor 110. The conductive feature 120 may be fabricated by the processes for forming conductive contacts, such as metal-to-poly (MP) contacts, of a transistor.

In some embodiments, the semiconductor device 1a includes conductive vias 130. Each of the conductive vias 130 is disposed over and electrically connected to a corresponding one of the conductive features 120. In some embodiments, the conductive via 130 is located at an elevation, with respect to the upper surface of the substrate 102, higher than that of the conductive feature 120. The conductive via 130 may be fabricated by the processes for forming conductive vias, such as a via zero (V0) layer, of a transistor.

In some embodiments, the semiconductor device 1a includes a parallel capacitor 140. The parallel capacitor 140 is disposed over and electrically connected to the conductive via 130. The parallel capacitor 140 may be fabricated by the processes for forming metal lines, such as metal one (M1) layer, of a transistor. The parallel capacitor 140 is electrically connected to the parallel capacitor 110 through the conductive feature 120 and the conductive via 130. In some embodiments, at least a portion of the parallel capacitor 140 functions as an electrode of a capacitor structure.

In some embodiments, the semiconductor device 1a includes conductive via 144. The conductive via 144 is disposed over and electrically connected to the parallel capacitor 140. The parallel capacitor 140 may be fabricated by the processes for forming conductive vias, such as via one (V1) layers, of a transistor.

In some embodiments, the semiconductor device 1a includes a parallel capacitor 150. The parallel capacitor 150 is disposed over and electrically connected to the parallel capacitor 140. The parallel capacitor 150 is located at an elevation, with respect to the upper surface of the substrate 102, higher than that of the parallel capacitor 140. The parallel capacitor 150 may be fabricated by the processes for forming metal lines, such as metal two (M2) layers, of a transistor.

In some embodiments, the semiconductor device 1a includes conductive vias 154. Each of the conductive vias 154 is disposed over and electrically connected to the parallel capacitor 150. The conductive via 154 may be fabricated by the processes for forming conductive vias, such as via two (V2) layers, of a transistor.

In some embodiments, the semiconductor device 1a includes a parallel capacitor 160. The parallel capacitor 160 is disposed over and electrically connected to the parallel capacitor 150. The parallel capacitor 160 may be fabricated by the processes for forming metal lines, such as metal three (M3) layers, of a transistor. The parallel capacitor 160 is electrically connected to the parallel capacitor 150 through the conductive vias 154.

In some embodiments, the semiconductor device 1a includes conductive vias 164. Each of the conductive vias 164 is disposed over and electrically connected to the parallel capacitor 160. The conductive via 164 may be fabricated by the processes for forming conductive vias, such as via three (V3) layers, of a transistor.

In some embodiments, the semiconductor device 1a includes a parallel capacitor 170. The parallel capacitor 170 is disposed over and electrically connected to the parallel capacitor 160. The parallel capacitor 170 may be fabricated by the processes for forming metal lines, such as metal four (M4) layers, of a transistor. The parallel capacitor 170 is electrically connected to the parallel capacitor 160 through the conductive vias 164.

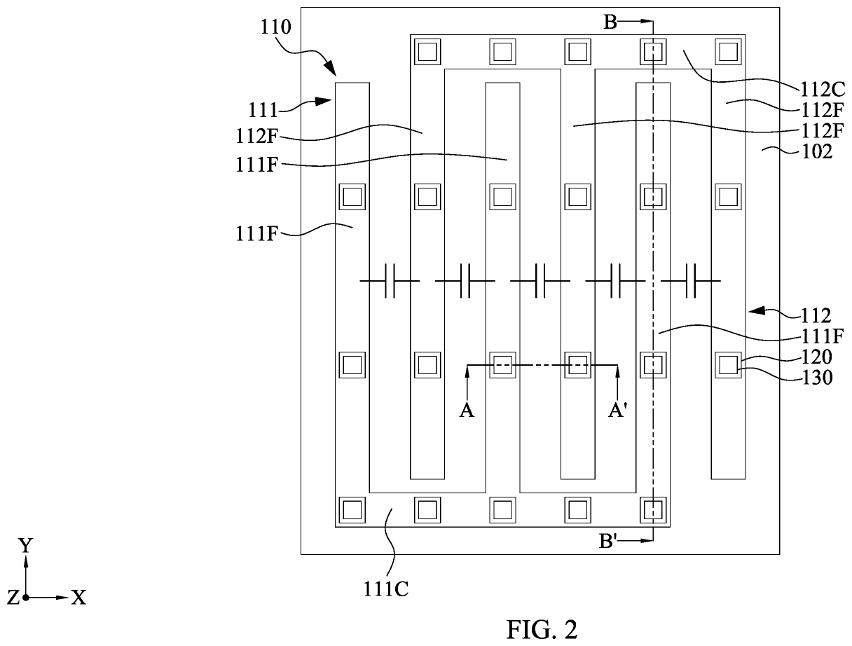

FIG. 2 illustrates the layout of the parallel capacitor 110, conductive features 120, and conductive vias 130 as shown in FIG. 1, in accordance with some embodiments of the present disclosure.

In some embodiments, the parallel capacitor 110 includes an electrode 111 and an electrode 112. The electrode 111 may be connected to a “high” terminal (e.g., a high voltage), and the electrode 112 may be connected to a “low” terminal (e.g., a low voltage). The electrode 111 includes a connected portion 111C and fingers 111F connected to the connected portion 111C. The connected portion 111C extends along the X-direction, and each of the fingers 111F extends along the Y-direction.

The electrode 112 includes a connected portion 112C and fingers 112F connected to the connected portion 112C. The connected portion 112C extends along the X-direction, and each of the fingers 112F extends along the Y-direction. In some embodiments, the fingers 111F and 112F are interdigitated and arranged alternatively.

Each of the conductive features 120 is disposed on the finger 111F, finger 112F, connected portion 111C or connected portion 112C. The location and the quantity of the conductive features 120 are merely exemplary, and the present disclosure is not intended to be limiting. For example, the conductive features 120 are only disposed or formed on the connected portions 111C and 112C, and the fingers 111F and 112F are free from overlapping the conductive feature 120 along the Z-direction in other embodiments.

Each of the conductive vias 130 is disposed on and electrically connected to a corresponding conductive feature 120.

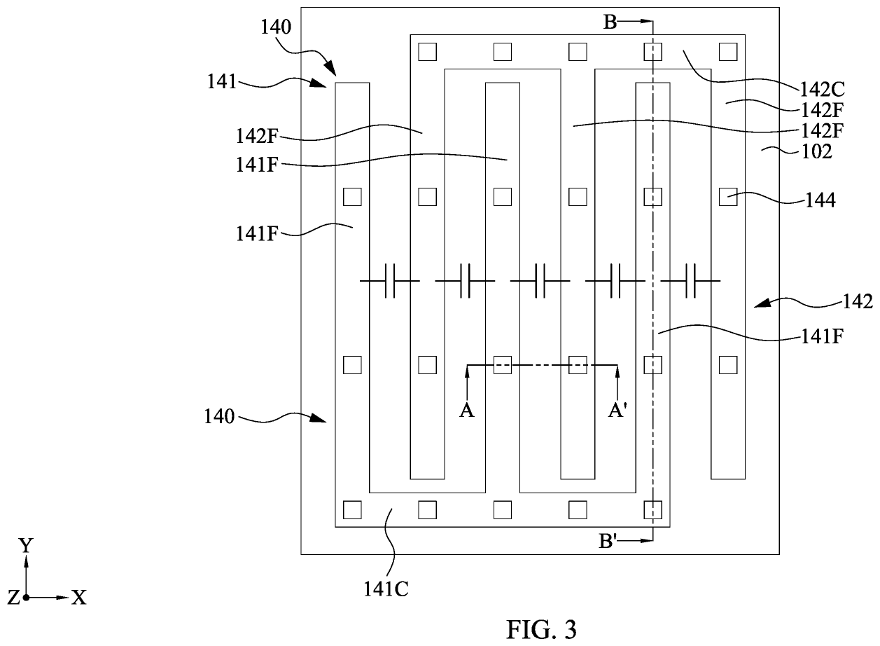

FIG. 3 illustrates a layout of the parallel capacitor 140 and the conductive vias 144 as shown in FIG. 1, in accordance with some embodiments of the present disclosure.

In some embodiments, the parallel capacitor 140 includes an electrode 141 and an electrode 142. The electrode 141 is connected to the electrode 111 through the conductive features 120 and the conductive vias 130. The electrode 141 includes a connected portion 141C and fingers 141F connected to the connected portion 141C. The connected portion 141C extends along the X-direction, and the finger 141F extends along the Y-direction.

The electrode 142 includes a connected portion 142C and fingers 142F connected to the connected portion 142C. The electrode 142 is connected to the electrode 112 through the conductive features 120 and the conductive vias 130. The connected portion 142C extends along the X-direction, and the finger 142F extends along the Y-direction. In some embodiments, the fingers 141F and 142F are interdigitated and arranged alternatively.

In some embodiments, the electrode 141 has a profile, including the dimension (e.g., size) and shape, substantially the same as or similar to that of the electrode 111. For example, the connected portion 141C overlaps the connected portion 111C along the Z-direction. The finger 141F overlaps a corresponding one of the finger 111F along the Z-direction; the connected portion 142C overlaps the connected portion 112C along the Z-direction, and the finger 142F overlaps a corresponding one of the finger 112F along the Z-direction.

Each of the conductive vias 144 is disposed on the electrode 141 or 142. The location and the quantity of the conductive vias 144 are merely exemplary, and the present disclosure is not intended to be limiting. For example, the conductive via 144 is only disposed or formed on the connected portions 141C and 142C, and the fingers 141F and 142F are free from overlapping the conductive via 144 along the Z-direction in other embodiments.

Each of the parallel capacitors 150, 160, and 170 may have a layout (or profile) the same as or similar to that of the parallel capacitor 140, and the descriptions of the parallel capacitors 150, 160, and 170 are omitted for brevity.

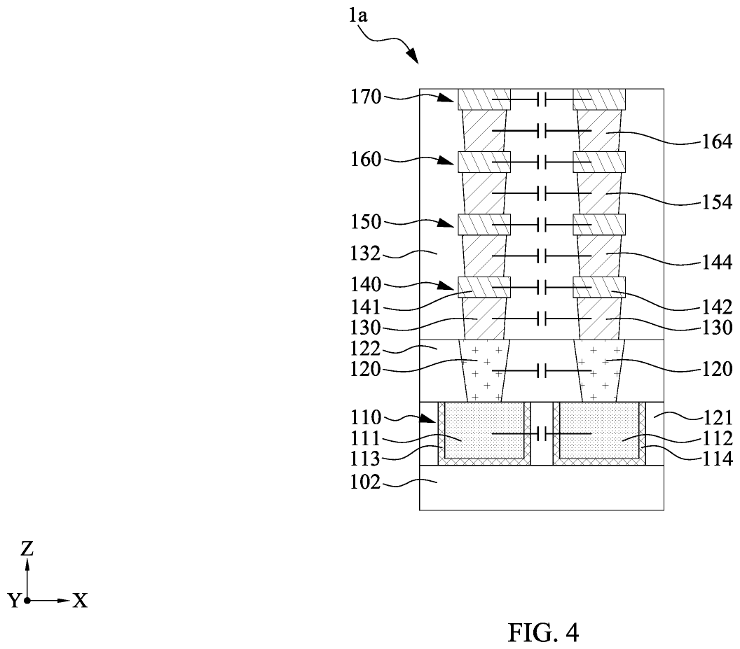

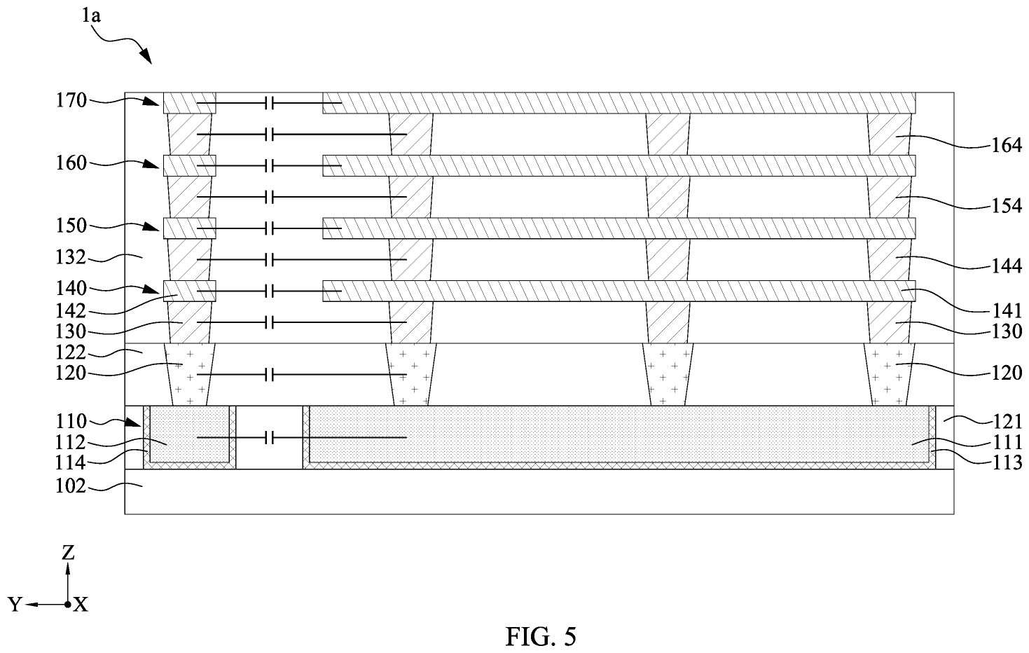

FIG. 4 and FIG. 5 illustrate cross-sectional views along line A-A′ and line B-B′ of the semiconductor device 1a, in accordance with some embodiments of the present disclosure.

In some embodiments, the substrate 102 is a semiconductor substrate, such as a bulk semiconductor substrate, a semiconductor-on-insulator (SOI) substrate, or the like, which may be doped (e.g., with a p-type or an n-type dopant) or undoped. The substrate 102 may be a semiconductor wafer, such as a silicon wafer. Generally, an SOI substrate includes a layer of a semiconductor material (e.g., silicon) formed on an insulator layer. The insulator layer may be, for example, a buried oxide (BOX) layer, a silicon oxide layer, or the like. The insulator layer is provided on a substrate, typically silicon or glass substrate. Other substrates, such as a multi-layered or gradient substrate, may also be used. In some embodiments, the semiconductor material of the substrate 102 may include or be made of silicon, germanium, a compound semiconductor including silicon carbide (SiC), gallium arsenic (GaAs), gallium phosphide (GaP), indium phosphide (InP), indium arsenide (InAs), and/or indium antimonide (InSb), an alloy semiconductor including SiGe, GaAsP, AlInAs, AlGaAs, GaInAs, GaInP, and/or GaInAsP, or combinations thereof.

Depending on design requirements, the substrate 102 may be a p-type substrate, an n-type substrate, or a combination thereof, and may have doped regions therein.

In some embodiments, the electrodes 111 and 112 are disposed on the substrate 102. In some embodiments, the electrodes 111 and 112 include a conductive material, such as tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), titanium nitride (TiN), tungsten nitride (WN), tantalum nitride (TaN), ruthenium (Ru) or a combination thereof. In some embodiments, the electrodes 111 and 112 include a semiconductor material, such as polysilicon. A capacitance may be stored or exhibited between the electrodes 111 and 112.

The semiconductor device 1a further includes a dielectric layer 113 and a dielectric layer 114. The dielectric layer 113 is disposed between the electrode 111 and the substrate 102. The dielectric layer 114 is disposed between the electrode 112 and the substrate 102. In some embodiments, the dielectric layer 113 further covers the lateral surface (not annotated) of the electrode 111. The dielectric layer 114 further covers the lateral surface (not annotated) of the electrode 112. In some embodiments, the dielectric layers 113 and 114 include one or more suitable dielectric materials such as silicon oxide (SiO₂), silicon nitride (Si₃N₄), silicon oxynitride (SiON), low-k dielectrics such as carbon doped oxides, extremely low-k dielectrics such as porous carbon doped silicon dioxide, a polymer such as polyimide, the like, or a combination thereof. In other embodiments, the dielectric layers 113 and 114 include dielectric materials having a high dielectric constant (k value), for example, greater than 3.9. The materials may include metal oxides such as hafnium oxide (HfO₂), hafnium zirconium oxide (HfZrOₓ), hafnium silicon oxide (HfSiOₓ), hafnium titanium oxide (HfTiOₓ), hafnium aluminum oxide (HfAlOₓ), titanium nitride (TiN), yttrium oxide (Y₂O₃), zirconium oxide (ZrO₂), the like, or a combination thereof.

The conductive feature 120 is disposed on the electrode 111 or 112. In some embodiments, the conductive feature 120 is tapered toward the substrate 102. In some embodiments, the conductive feature 120 includes a barrier layer and a conductive material surrounded by the barrier layer. The barrier layer includes metal, metal oxide, metal nitride, metal carbide, metal alloy, or suitable materials. For example, the barrier layer includes tantalum nitride, tantalum, titanium nitride, titanium, cobalt tungsten, tungsten nitride, or the like. The conductive material includes tungsten, copper, ruthenium, iridium, nickel, osmium, rhodium, aluminum, molybdenum, cobalt, tantalum, alloys thereof, and combinations thereof. A capacitance may be stored or exhibited between the conductive features 120.

The semiconductor device 1a further includes a dielectric structure 121. The dielectric structure 121 is disposed on the substrate 102. The parallel capacitor 110 is at least partially embedded within the dielectric structure 121. The dielectric structure 121 includes an oxygen-containing dielectric material, which may include silicon-oxide based materials such as tetra ethyl ortho silicate (TEOS) oxide, plasma-enhanced CVD (PECVD) oxide (SiO₂), phospho-silicate glass (PSG), boron-silicate glass (BSG), boron-doped phospho-silicate glass (BPSG), or other suitable materials. The dielectric structure 121 may also be referred to as an interlayer dielectric zero (ILD 0) layer. Although not shown, the semiconductor device 1a may further include other dielectric layers for different purposes. For example, the semiconductor device 1a may include a contact etch stop layer (CESL) between the substrate 102 and the dielectric structure 121, which includes or is made of silicon nitride, silicon carbo-nitride, or the like.

The semiconductor device 1a further includes a dielectric structure 122. The dielectric structure 122 is disposed on the dielectric structure 121. The conductive feature 120 is at least partially embedded within the dielectric structure 122. In some embodiments, the material of the dielectric structure 122 is the same as or similar to that of the dielectric structure 121. The dielectric structure 122 may also be referred to as an interlayer dielectric first (ILD 1) layer.

The conductive via 130 is disposed on and electrically connected to the conductive feature 120. In some embodiments, the conductive via 130 is tapered toward the substrate 102. In some embodiments, the conductive via 130 includes a barrier layer and a conductive material surrounded by the barrier layer. In some embodiments, the material of the conductive feature 120 is different from the conductive via 130. For example, the barrier layer of the conductive feature 120 includes titanium nitride, and the barrier layer of the conductive via 130 includes tantalum nitride. The conductive material of the conductive feature 120 includes tungsten, and the conductive material of the conductive via 130 includes copper. A capacitance may be stored or exhibited between the conductive vias 130.

In some embodiments, the lateral surface (or sidewall) of the conductive feature 120 and the lateral surface (or sidewall) of the conductive via 130 are discontinuous, noncoplanar or disconnected. A portion of the upper surface of the conductive feature 120 is exposed by the conductive via 130. In some embodiments, the conductive feature 120 and the conductive via 130 are formed by different stages (or processes) for an aspect ratio issue.

The electrodes 141 and 142 are disposed on the conductive via 130. Each of the electrodes 141 and 142 includes a barrier layer and a conductive material surrounded by the barrier layer. A capacitance may be stored or exhibited between the electrode 141 and electrode 142.

The structures and the materials of the parallel capacitors 150, 160, and 170 may be the same as or similar to those of the parallel capacitor 140. For example, each of the parallel capacitors 150, 160, and 170 may have a first electrode electrically connected to the electrode 141 and a second electrode electrically connected to the electrode 142. Further, the structures and the materials of the conductive vias 154 and 164 may be the same as or similar to those of the conductive via 144. The descriptions of the above features are omitted for brevity.

The semiconductor device 1a further includes a dielectric structure 132. The dielectric structure 132 is disposed on the dielectric structure 122. The dielectric structure 132 encapsulates the parallel capacitors 140, 150, 160, and 170 as well as conductive vias 144, 154, and 164. In some embodiments, the dielectric structure 132 includes multiple layers which are formed by different stages and/or processes. The material of the dielectric structure 132 is the same as or similar to that of the dielectric structure 121.

In comparison with a comparative semiconductor device, the capacitance of the semiconductor device 1a is increased by 20 to 30%, including the contribution of the capacitance exhibited between the electrodes 111 and 112 as well as the capacitance between the conductive features 120.

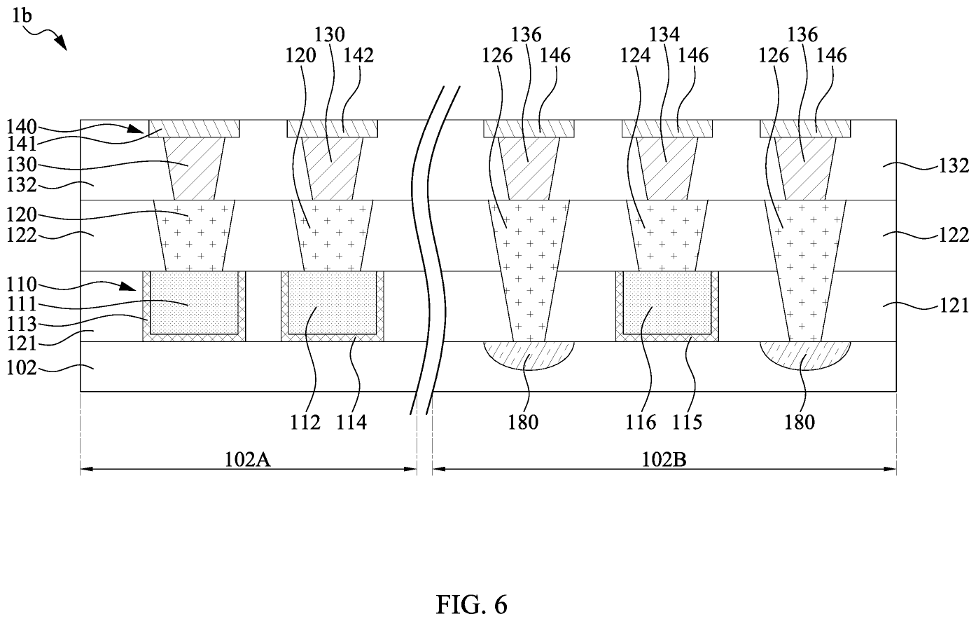

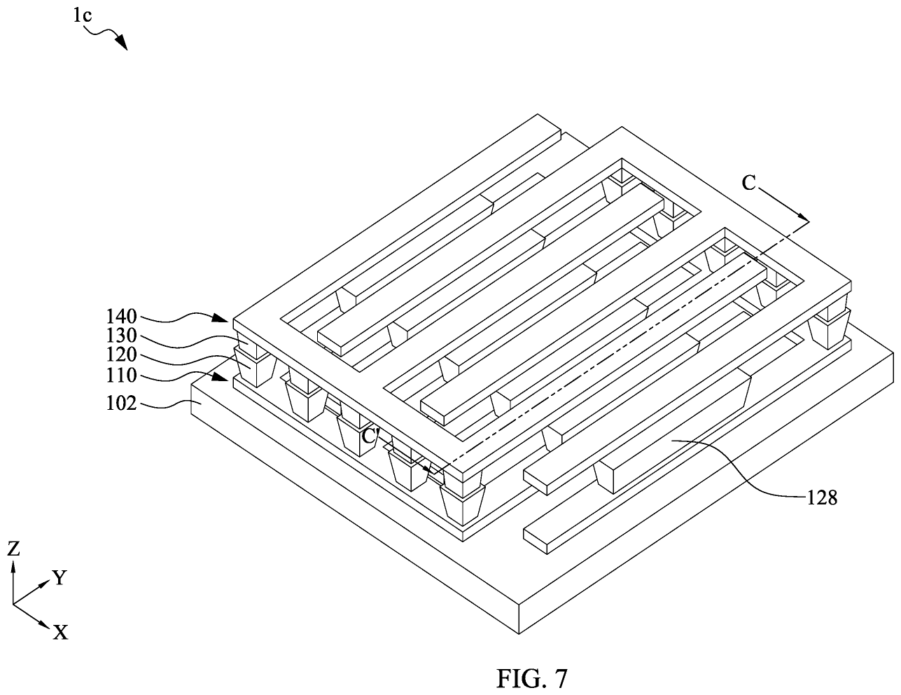

FIG. 6 illustrates a cross-sectional view of a semiconductor device 1b, in accordance with some embodiments of the present disclosure. In some embodiments, the substrate 102 includes a capacitor region 102A and a transistor region 102B. The capacitor region 102A is configured to form or define a capacitor structure, such as the capacitor structure included in the semiconductor device 1a as shown in FIG. 1 to FIG. 5. The transistor region 102B is configured to form or define a transistor. It should be noted that some features are omitted for brevity. For example, the M2, M3, and M4 layers as well as the V1, V2 and V3 layers are omitted from FIG. 6.

The semiconductor device 1b includes a gate dielectric 115 and a gate electrode 116. The gate dielectric 115 is disposed on the transistor region 102B of the substrate 102. In some embodiments, the material of the gate dielectric 115 is the same as or similar to that of the dielectric layer 113 (or dielectric layer 114). The gate electrode 116 is disposed on the gate dielectric 115. In some embodiments, the material of the gate electrode 116 is the same as or similar to that of the electrode 111 (or electrode 112). For example, the gate electrode 116 includes a gate electrode material including tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), titanium nitride (TiN), tungsten nitride (WN), tantalum nitride (TaN), ruthenium (Ru) or a combination thereof.

The semiconductor device 1b includes a source/drain (S/D) feature 180. The S/D feature 180 is disposed on the transistor region 102B. The S/D feature 180 is disposed on, for example, two opposite sides of the gate electrode 116. In some embodiments, the S/D feature 180 may be formed by implanting n-type dopants or p-type dopants. The n-type dopant includes phosphorus (P), arsenic (As), antimony (Sb), bismuth (Bi), or a combination thereof. The p-type dopant includes boron (B) or other suitable dopants. In some embodiments, the transistor region 102B includes a FinFET, and the S/D feature 180 may include silicon germanium boron (SiGeB), GeB, silicon phosphorous (SiP), silicon carbon phosphorous (SiCP), allium arsenic (GaAs), indium phosphide (InP), other suitable semiconductor materials, and a combination thereof formed on fins.

The semiconductor device 1b includes a conductive contact 124. The conductive contact 124 is disposed on and electrically connected to the gate electrode 116. The conductive contact 124 penetrates at least a portion of the dielectric structure 122. In some embodiments, the material of the conductive contact 124 is the same as or similar to that of the conductive feature 120. The conductive contact 124 may also be referred to as an MP contact.

The semiconductor device 1b includes conductive contacts 126. The conductive contact 126 is disposed on and electrically connected to the S/D feature 180. The conductive contact 126 penetrates at least a portion of the dielectric structures 121 and 122. In some embodiments, the material of the conductive contact 126 is the same as or similar to that of the conductive contact 124. The conductive contact 126 may also be referred to as metal-to-device (MD) contact.

The semiconductor device 1b includes conductive vias 134 and 136. The conductive via 134 is disposed on and electrically connected to the conductive contact 124. The conductive via 136 is disposed on and electrically connected to the conductive contact 126. In some embodiments, the material of the conductive vias 134 and 136 is the same as or similar to that of the conductive via 130. Each of the conductive vias 134 and 136 may also be referred to as a V0 layer.

The semiconductor device 1b includes metal lines 146. The metal line 146 is disposed on and electrically connected to the conductive via 134 (or conductive via 136). In some embodiments, the material of the metal line 146 is the same as or similar to that of the electrode 141. The metal line 146 may also be referred to as an M1 layer.

In this embodiment, the features of the capacitor structure on the capacitor region 102A can correspond to those of the transistor on the transistor region 102B. The processes for manufacturing the capacitor structure can be integrated with those for manufacturing the transistor. As a result, no additional mask, processes, and/or stages are required. Therefore, the semiconductor device 1b can have a relatively great capacitance without additional manufacturing cost.

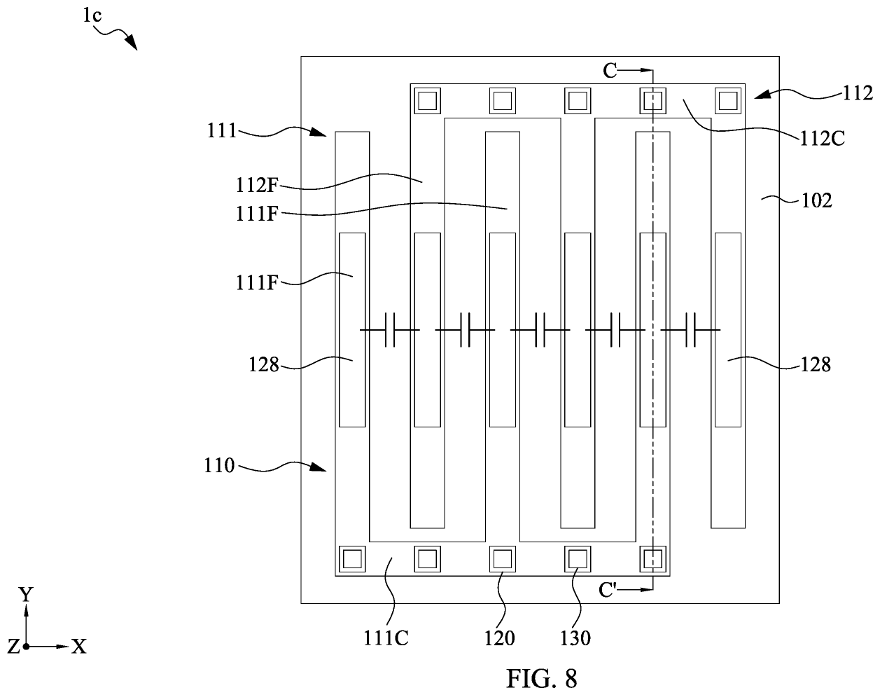

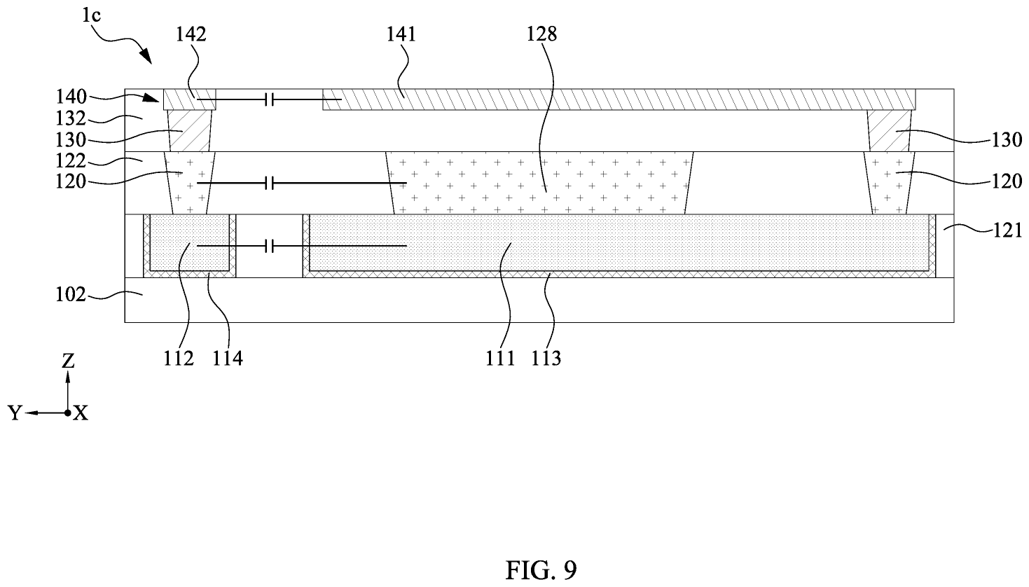

FIG. 7, FIG. 8, and FIG. 9 illustrate a semiconductor device 1c, in accordance with some embodiments of the present disclosure, wherein FIG. 7 is a perspective view, FIG. 8 illustrates a layout, and FIG. 9 is a cross-sectional view along line C-C′ of FIG. 7. It should be noted that some features are omitted from FIG. 8 and FIG. 9 for brevity. For example, the parallel capacitor 140 is omitted from FIG. 8. Further, the structures of the parallel capacitors 150, 160, and 170 as well as conductive vias 144, 154 and 164 as shown in FIG. 1 to FIG. 5 are omitted from FIG. 7 to FIG. 9 for brevity.

Referring to FIG. 7, the semiconductor device 1c includes conductive feature 128. Each of the conductive features 128 is disposed between the parallel capacitors 110 and 140. The conductive feature 128 may be fabricated by the processes for forming conductive contacts, such as MP contacts, of a transistor.

Referring to FIG. 8, each of the conductive features 128 is disposed on the finger 111F or 112F. The conductive features 128 may be arranged along the X-direction. The conductive feature 128 is spaced apart from the conductive feature 120. In some embodiments, each of the conductive features 128 extends along the Y-direction. In some embodiments, the conductive feature 128 has a bar-shaped profile or other suitable profiles. In some embodiments, the conductive feature 128 has a length less than that of the finger 111F (or 112F) along the Y-direction. A capacitance may be stored or exhibited between the conductive features 128. In some embodiments, the conductive feature 128 has a dimension (e.g., surface area of the upper surface and/or lateral surface) greater than that of the conductive feature 120 (or conductive via 130).

Referring to FIG. 9, the conductive feature 128 is embedded within the dielectric structure 122. In some embodiments, the conductive feature 128 is spaced apart from the parallel capacitor 140. In some embodiments, the conductive feature 128 is free from overlapping the conductive via 130, as shown in FIG. 7, along the Z-direction.

In this embodiment, the conductive feature 128 has a greater surface area (e.g., the surface area of the lateral surface), which thereby increases the capacitance of the semiconductor device 1c.

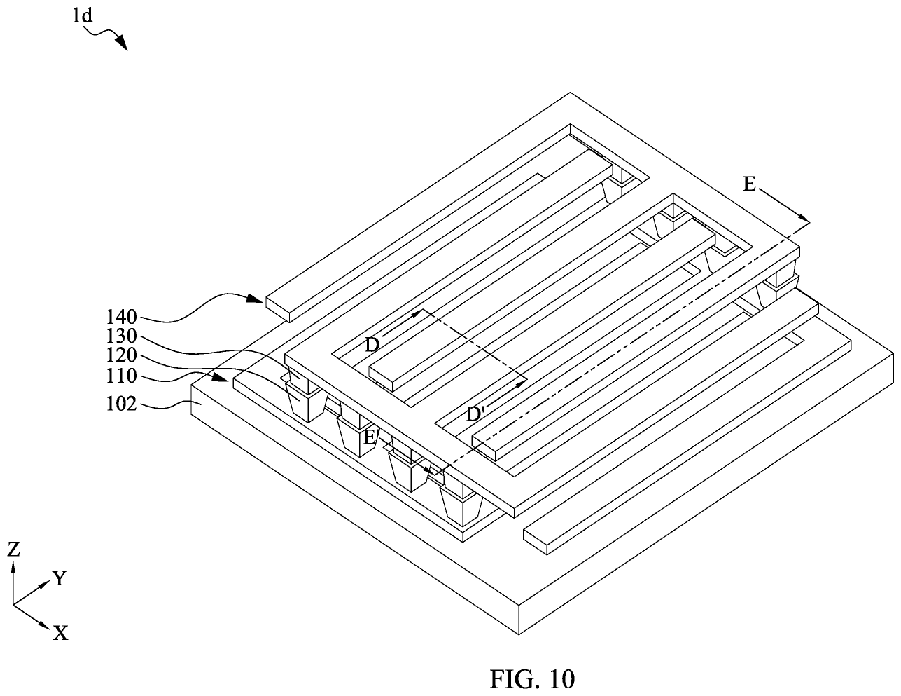

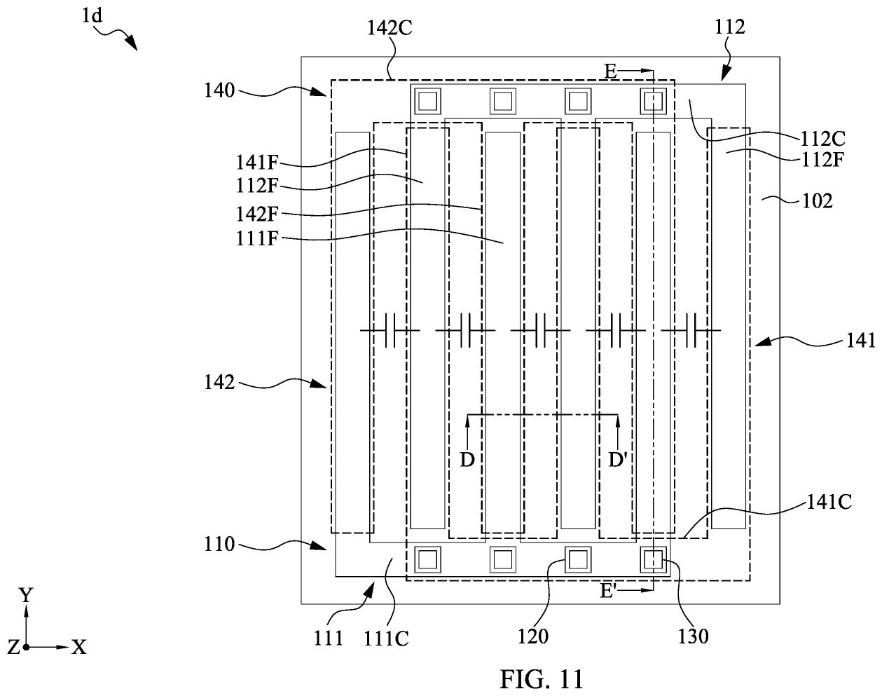

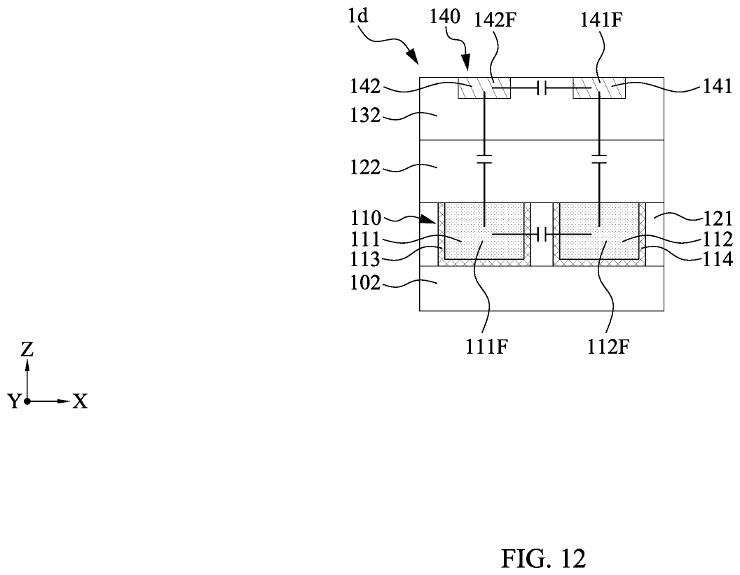

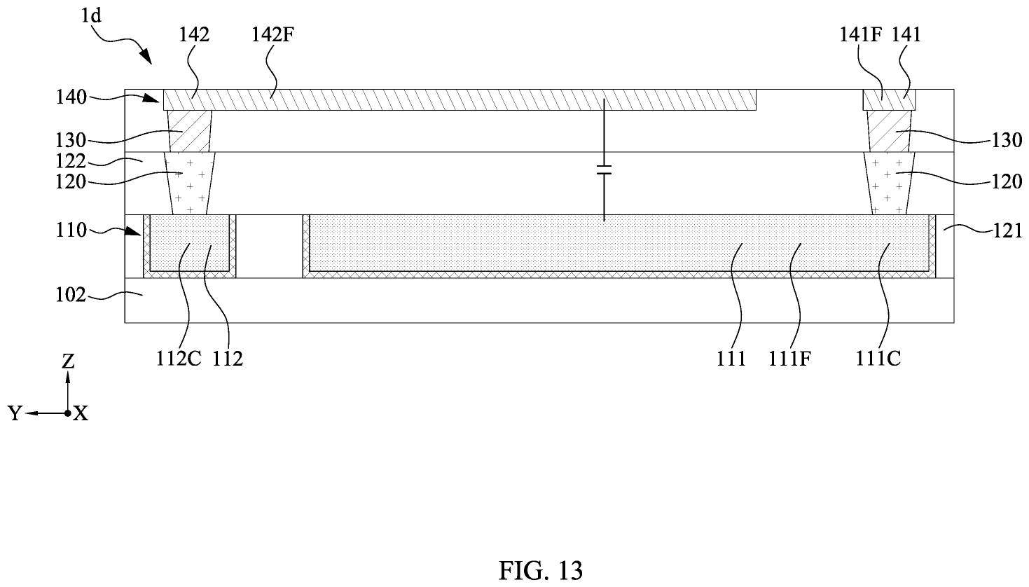

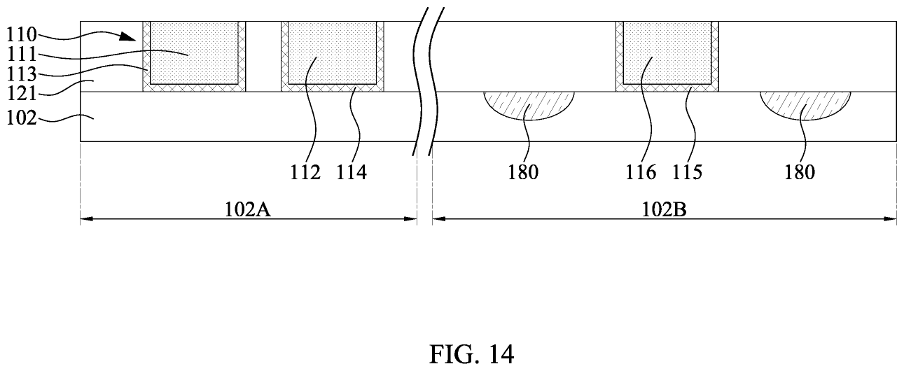

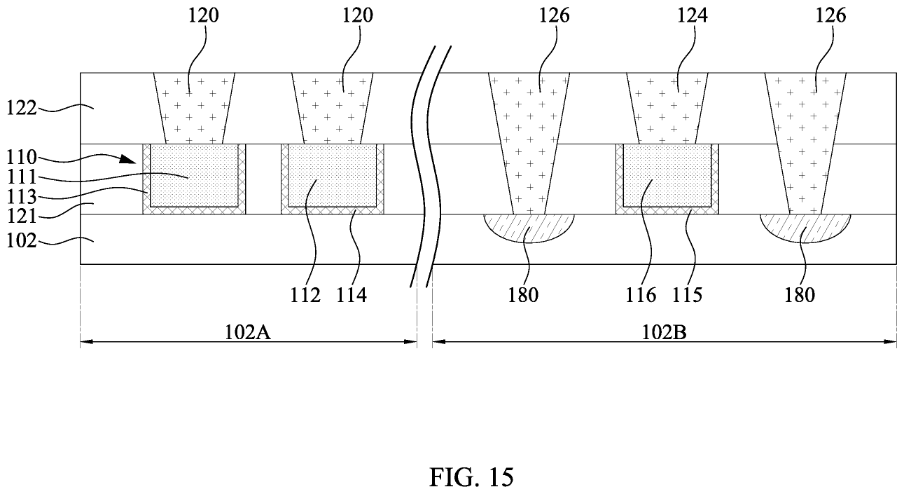

FIG. 10, FIG. 11, FIG. 12, and FIG. 13 illustrate a semiconductor device 1d, in accordance with some embodiments of the present disclosure, wherein FIG. 10 is a perspective view, FIG. 11 illustrates layouts of parallel capacitors, FIG. 12 is a cross-sectional view along line D-D′ of FIG. 10, and FIG. 13 is a cross-sectional view along line E-E′ of FIG. 10. It should be noted that some features are omitted from FIG. 10 to FIG. 13 for brevity. For example, the structures of the parallel capacitors 150, 160, and 170 as well as conductive vias 144, 154 and 164 as shown in FIG. 1 to FIG. 5 are omitted from FIG. 10 to FIG. 13 for brevity.

Referring to FIG. 10, the electrodes 141 and 142 of the parallel capacitor 140 may be shifted. In some embodiments, the electrode 141 overlaps the electrode 112 along the Z-direction. In some embodiments, the electrode 142 overlaps the electrode 111 along the Z-direction.

Referring to FIG. 11, the electrodes 141 and 142 of the parallel capacitor 140 is presented by a dashed line. The finger 111F overlaps the finger 142F. In some embodiments, the finger 112F overlaps the finger 141F. In some embodiments, the electrode 111 is free from overlapping the electrode 142 along the Z-direction. In some embodiments, a portion of the electrode 111 is exposed by the electrodes 141 and 142 in a top view. In some embodiments, a portion of the connected portion 111C is exposed by the electrodes 141 and 142 in a top view. In some embodiments, a portion of the finger 111F is exposed by the electrodes 141 and 142 in a top view. In some embodiments, a portion of the electrode 112 is exposed by the electrodes 141 and 142 in a top view. In some embodiments, a portion of the connected portion 112C is exposed by the electrodes 141 and 142 in a top view. In some embodiments, a portion of the finger 112F is exposed by the electrodes 141 and 142 in a top view.

Referring to FIG. 12 and FIG. 13, a capacitance may be stored or exhibited between the electrode 111 (or finger 111F) and electrode 142 (or finger 142F). A capacitance may be stored or exhibited between the electrode 112 (or finger 112F) and electrode 141 (or finger 141F). In some embodiments, the finger 111F is free from overlapping the finger 141F along the Z-direction. In some embodiments, the finger 112F is free from overlapping the finger 142F along the Z-direction.

In this embodiment, more capacitance can be exhibited between the shifted electrode 141 and the electrode 112 as well as between the shifted electrode 142 and the electrode 111. Therefore, the capacitance is further increased in the semiconductor device 1d.

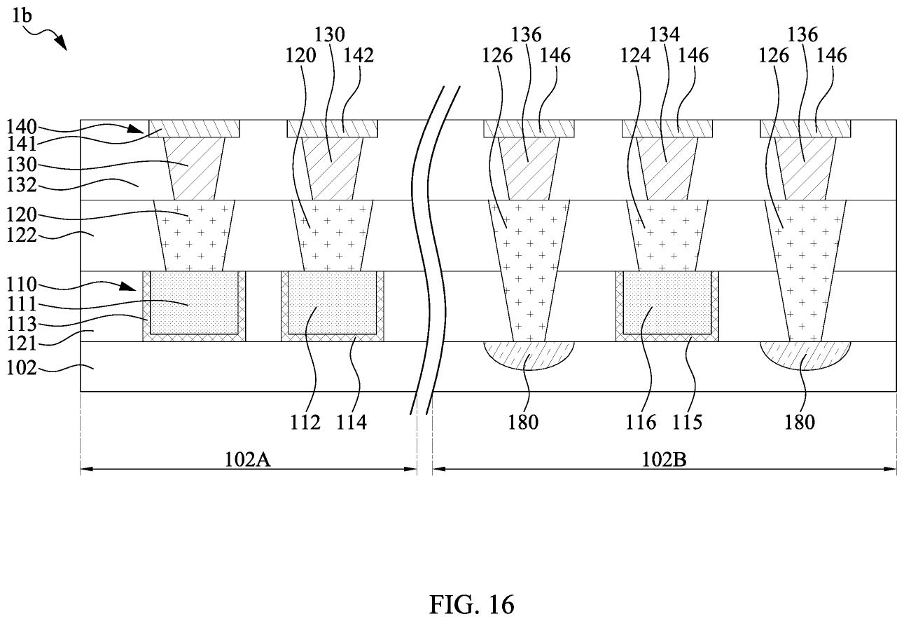

FIG. 14, FIG. 15, and FIG. 16 illustrate various stages of manufacturing a semiconductor device, in accordance with some embodiments of the present disclosure.

Referring to FIG. 14, a substrate 102 is provided. The substrate 102 includes a capacitor region 102A and a transistor region 102B. Electrodes 111 and 112 as well as dielectric layers 113 and 114 are formed on the capacitor region 102A. A gate dielectric 115 and a gate electrode 116 are formed on the transistor region 102B, which can be formed by chemical vapor deposition (CVD), physical vapor deposition (PVD), atomic layer deposition (ALD), high density plasma CVD (HDPCVD), metal organic CVD (MOCVD), remote plasma CVD (RPCVD), plasma enhanced CVD (PECVD), low-pressure CVD (LPCVD), atomic layer CVD (ALCVD), atmospheric pressure CVD (APCVD), plasma enhanced ALD (PEALD), plating, other suitable methods, or combinations thereof. An S/D feature 180 is formed on two opposite sides of the gate electrode 116. A dielectric structure 121 is formed to encapsulate the electrodes 111 and 112 and the gate electrode 116. The dielectric structure 121 is formed by CVD, PVD, ALD, HDPCVD, MOCVD, RPCVD, PECVD, LPCVD, ALCVD, APCVD, PEALD, other suitable methods, or combinations thereof.

In some embodiments, a dummy gate stack (not shown) is formed on the capacitor region 102A and the transistor region 102B. The dielectric structure 121 is formed to cover the dummy gate stack. A chemical mechanical polishing (CMP) process may be performed to remove excessive dielectric structure 121 until the dummy gate stack is exposed. The dummy gate stack is removed to define openings over the capacitor region 102A and the transistor region 102B. A gate dielectric material and a gate electrode material are formed within the openings to produce the structure as shown in FIG. 14. However, the present disclosure is not intended to be limiting.

Referring to FIG. 15, a dielectric structure 122 is formed on the dielectric structure 121. The dielectric structure 122 may be formed by CVD, PVD, ALD, HDPCVD, MOCVD, RPCVD, PECVD, LPCVD, ALCVD, APCVD, PEALD, other suitable methods, or combinations thereof. Conductive features 120, and conductive contacts 124 and 126 are formed to penetrate the dielectric structure 121 and/or 122. The dielectric structure 121 and/or 122 may be patterned to define openings over the capacitor region 102A and the transistor region 102B. The conductive features 120 and conductive contacts 124 and 126 may be formed within said openings. The barrier layers and the conductive materials of the conductive feature 120 and conductive contacts 124 and 126 may be formed by CVD, PVD, ALD, HDPCVD, MOCVD, RPCVD, PECVD, LPCVD, ALCVD, APCVD, PEALD, electroplating, electroless plating, other suitable deposition methods, or combinations thereof.

Referring to FIG. 16, a dielectric structure 132 is formed on the dielectric structure 122. The dielectric structure 132 may include multiple layers and may be formed by CVD, PVD, ALD, HDPCVD, MOCVD, RPCVD, PECVD, LPCVD, ALCVD, APCVD, PEALD, other suitable methods, or combinations thereof. The conductive vias 130, 134, and 136 may be formed on the conductive features 120. Electrodes 141 and 142, and the metal line 146 are formed on the conductive vias 130, 134, or 136. The electrodes 141 and 142 as well as the metal line 146 may be formed by CVD, PVD, ALD, HDPCVD, MOCVD, RPCVD, PECVD, LPCVD, ALCVD, APCVD, PEALD, electroplating, electroless plating, other suitable deposition methods, or combinations thereof. The capacitor structure can be defined on the capacitor region 102A, and the transistor can be defined on the transistor region 102B. As a result, a semiconductor device (e.g., the semiconductor device as shown in FIG. 6) can be produced.

In some embodiments of present disclosure, the processes for forming a capacitor structure and the processes for forming a transistor can be integrated without additional steps and masks. The capacitance of the semiconductor device is increased without additional cost.

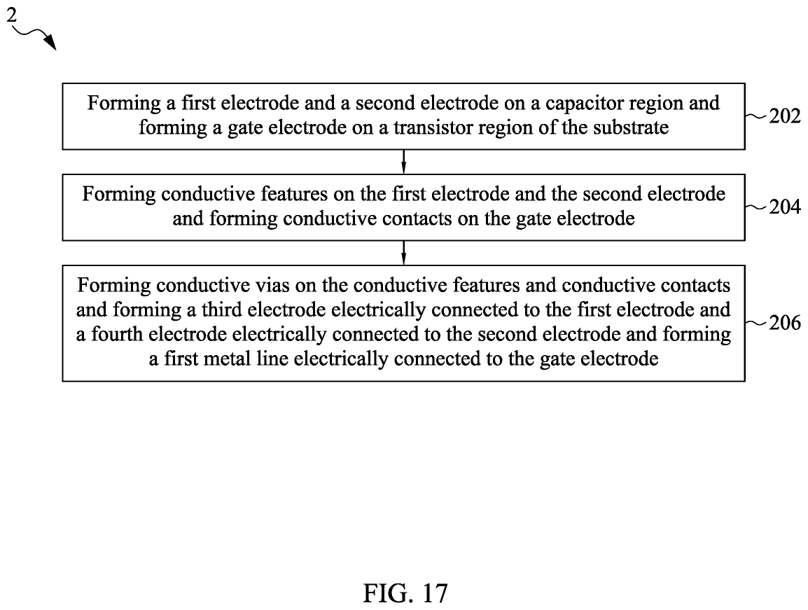

FIG. 17 is a flowchart of a method 2 for manufacturing a semiconductor device according to various aspects of the present disclosure.

The method 2 begins with operation 202 in which a substrate is provided. The substrate includes a capacitor region and a transistor region. The first electrode and second electrode of a capacitor are formed on the capacitor region. The gate electrode of a capacitor is formed on the transistor region. FIG. 14 depicts a stage corresponding to operation 202.

The method 2 continues with operation 204 in which conductive features are formed on the first electrode and the second electrode. Conductive contacts are formed on the gate electrode and S/D features. FIG. 15 depicts a stage corresponding to operation 204.

The method 2 continues with operation 206 in which conductive vias are formed over the conductive feature and the conductive vias. The third electrode and the fourth electrode are formed on the first electrode and the second electrode, respectively. The M1 layer is formed. FIG. 16 depicts a stage corresponding to operation 206.

The method 2 is merely an example, and is not intended to limit the present disclosure beyond what is explicitly recited in the claims. Additional operations can be provided before, during, and after the method 2, and some operations described can be replaced, eliminated, or reordered for additional embodiments of the method.

Some embodiments of the present disclosure provide a semiconductor device. The semiconductor device includes a substrate, a transistor, and a capacitor structure. The transistor includes a gate electrode material. The capacitor structure includes a first electrode and a second electrode including the gate electrode material. The capacitor structure also includes a plurality of first conductive features disposed over the first electrode and a plurality of conductive vias disposed over a corresponding one of the plurality of first conductive features. The capacitor structure further includes a third electrode over the plurality of conductive vias and electrically connected to the first electrode through the plurality of first conductive features and the plurality of conductive vias.

Some embodiments of the present disclosure provide a semiconductor device. The semiconductor device includes a substrate and a capacitor structure on the substrate. The capacitor structure includes a first electrode and a second electrode exhibiting a parallel capacitor. The first electrode includes a plurality of fingers extending along a first direction. The capacitor also includes a third electrode electrically connected to the first electrode and including a plurality of fingers extending along the first direction. The plurality of fingers of the first electrode is free from vertically overlapping the plurality of fingers of the third electrode.

Some embodiments of the present disclosure provide a method of manufacturing a semiconductor device. The method includes: providing a substrate having a transistor region and a capacitor region; forming a gate electrode on the transistor region, wherein the gate electrode comprises a gate electrode material; forming a first electrode and a second electrode on the capacitor region, wherein the first electrode and the second electrode exhibit a first parallel capacitor and comprise the gate electrode material; forming a first metal line over the gate electrode; and forming a third electrode over the first electrode and a fourth electrode over the second electrode, wherein the third electrode and the fourth electrode exhibit a second parallel capacitor, and the third electrode is located at an elevation substantially the same as that of the first metal line.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a transistor comprising a gate electrode on the substrate, wherein the gate electrode comprises a gate electrode material;
a capacitor structure, comprising:
a first electrode and a second electrode on the substrate, wherein the first electrode and the second electrode comprise the gate electrode material;
a plurality of first conductive features disposed over the first electrode, wherein each of the plurality of first conductive features is tapered toward the substrate;
a plurality of conductive vias, each of which is disposed over a corresponding one of the plurality of first conductive features, wherein each of the plurality of conductive vias is tapered toward the substrate; and
a third electrode over the plurality of conductive vias, wherein the third electrode is electrically connected to the first electrode through the plurality of first conductive features and the plurality of conductive vias.

2. The semiconductor device of claim 1, further comprising:
a plurality of second conductive features disposed over the first electrode, wherein each of the plurality of second conductive features has a surface area greater than that of each of the first conductive features.

3. The semiconductor device of claim 2, wherein each of the plurality of second conductive features is free from overlapping the plurality of conductive vias.

4. The semiconductor device of claim 2, wherein the first electrode comprises a plurality of fingers extending along a first direction and a connected portion connected to the plurality of fingers and extending along a second direction different from the first direction, and wherein each of the plurality of second conductive features extends along the first direction.

5. The semiconductor device of claim 1, wherein the third electrode comprises a material different from the gate electrode material.

6. The semiconductor device of claim 1, wherein a lateral surface of each of the conductive vias and a lateral surface of the corresponding one of the plurality of first conductive features are discontinuous.

7. The semiconductor device of claim 1, wherein the first electrode is free from vertically overlapping the third electrode.

8. The semiconductor device of claim 7, wherein the first electrode comprises a plurality of fingers extending along a first direction and a connected portion connected to the plurality of fingers and extending along a second direction different from the first direction, and the third electrode comprises a plurality of fingers free from vertically overlapping the plurality of fingers of the first electrode.

9. The semiconductor device of claim 8, wherein the plurality of fingers of the third electrode vertically overlap a plurality of fingers of the second electrode.

10. A semiconductor device, comprising:
a substrate;
a capacitor structure on the substrate, comprising:
a first electrode and a second electrode exhibiting a parallel capacitor, wherein the first electrode comprises a plurality of fingers extending along a first direction;
a third electrode electrically connected to the first electrode and comprising a plurality of fingers extending along the first direction, wherein the plurality of fingers of the first electrode is free from vertically overlapping the plurality of fingers of the third electrode.

11. The semiconductor device of claim 10, wherein the third electrode at least partially overlaps the second electrode.

12. The semiconductor device of claim 10, wherein the first electrode comprises a connected portion connected to the plurality of fingers of the first electrode, the third electrode comprises a connected portion connected to the plurality of fingers of the third electrode, and wherein the connected portion of the first electrode vertically overlaps the connected portion of the third electrode.

13. The semiconductor device of claim 12, wherein the capacitor structure further comprises a fourth electrode electrically connected to the second electrode, wherein a portion of the connected portion of the first electrode is free from vertically overlapping the third electrode and the fourth electrode.

14. The semiconductor device of claim 10, further comprising:
a transistor comprising a gate electrode disposed on the substrate, wherein a material of the gate electrode is the same as that of the first electrode.

15. The semiconductor device of claim 10, wherein a material of the first electrode is different from that of the third electrode.

16. The semiconductor device of claim 10, wherein the capacitor structure further comprises:
a first conductive feature disposed over the first electrode; and
a conductive via between the first conductive feature and the third electrode,
wherein a lateral surface of the first conductive feature is misaligned with a lateral surface of the conductive via.

17. The semiconductor device of claim 16, wherein a material of the first conductive feature is different from a material of the conductive via.

18. The semiconductor device of claim 16, further comprising;
a second conductive feature disposed over the first electrode and located at an elevation the same as that of the first conductive feature, wherein a surface area of the second conductive feature is greater than that of the first conductive feature.

19. A method of manufacturing a semiconductor device, comprising:
providing a substrate having a transistor region and a capacitor region;
forming a gate electrode on the transistor region, wherein the gate electrode comprises a gate electrode material;
forming a first electrode and a second electrode on the capacitor region, wherein the first electrode and the second electrode exhibit a first parallel capacitor and comprise the gate electrode material;
forming a first metal line over the gate electrode; and
forming a third electrode over the first electrode and a fourth electrode over the second electrode, wherein the third electrode and the fourth electrode exhibit a second parallel capacitor, and the third electrode is located at an elevation substantially the same as that of the first metal line.

20. The method of claim 19, further comprising:
forming a conductive feature over the first electrode; and
forming a conductive via over the conductive feature, wherein a material of the conductive feature is different from that of the conductive via.
